(19) United States
(12) Patent Application Publication
(10) Pub. No.: US 2026/0118423 A1
(43) Pub. Date: Apr. 30, 2026

(54) CIRCUIT FOR MEASURING DUTY CYCLE DISTORTION

(71) Applicant: QUALCOMM Incorporated, San Diego, CA (US)

(72) Inventors: Pratik Rajeshbhai PATEL, Bangalore (IN); Vamsi Krishna KUNTAMUKKALA, Hyderabad (IN); Raghavendra Raviraj JOISHI, Bangalore (IN)

(21) Appl. No.: 18/930,239

(22) Filed: Oct. 29, 2024

(51) Int. Cl. G01R 31/317; H03K 3/03; H03K 21/08

(52) U.S. Cl. CPC G01R 31/31727; H03K 21/08; H03K 3/0315

(57) ABSTRACT

A measurement circuit includes a ring oscillator, a first counter coupled to an output of the ring oscillator, and a second counter coupled to the output of the ring oscillator. The measurement circuit also includes a signal generator configured to receive a clock signal, generate a first count enable signal based the clock signal and output the first count enable signal to the first counter, and generate a second count enable signal based on the clock signal and output the second count enable signal to the second counter.

### BACKGROUND

### Field

Aspects of the present disclosure relate generally to signal measurements, and, more particularly, to circuits for measuring duty cycle distortion of a signal.

### Background

A system may include a clock generator (e.g., a phase-locked loop) configured to generate a clock signal for timing operations of one or more circuits (e.g., flip-flops) in the system. The system may also include a clock distribution network for distributing the clock signal from the clock generator to the one or more circuits. A challenge with clock distribution is duty cycle degradation in the clock distribution network (e.g., due to asymmetric aging). The duty cycle degradation results in duty cycle distortion in the clock signal, which can lead to timing issues (e.g., timing violations) in the one or more circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a measurement circuit. The measurement circuit includes a ring oscillator, a first counter coupled to an output of the ring oscillator, and a second counter coupled to the output of the ring oscillator. The measurement circuit also includes a signal generator configured to receive a clock signal, generate a first count enable signal based the clock signal and output the first count enable signal to the first counter, and generate a second count enable signal based on the clock signal and output the second count enable signal to the second counter.

A second aspect relates to a measurement method. The method includes receiving a clock signal, receiving an oscillator signal from a ring oscillator, counting a first number of periods of the oscillator signal in a period of the clock signal to generate a first count value, and counting a second number of periods of the oscillator signal in a phase of the clock signal to generate a second count value.

### BRIEF DESCRIPTION OF THE DRAWINGS

FIG. 1 shows an example of a system including a clock distribution network according to certain aspects of the present disclosure.

FIG. 2 shows an example of the system of FIG. 1 with duty cycle distortion correction according to certain aspects of the present disclosure.

FIG. 3 shows an example of a measurement circuit including a ring oscillator according to certain aspects of the present disclosure.

FIG. 4 shows an exemplary implementation of the ring oscillator according to certain aspects of the present disclosure.

FIG. 5 shows an exemplary implementation of time-to-digital converters according to certain aspects of the present disclosure.

FIG. 6 shows an exemplary implementation of a signal generator according to certain aspects of the present disclosure.

FIG. 7 is a timing diagram showing an example of signals related to the signal generator according to certain aspects of the present disclosure.

FIG. 8 shows an example of the measurement circuit coupled to a power management circuit according to certain aspects of the present disclosure.

FIG. 9 is a flowchart illustrating a measurement method according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

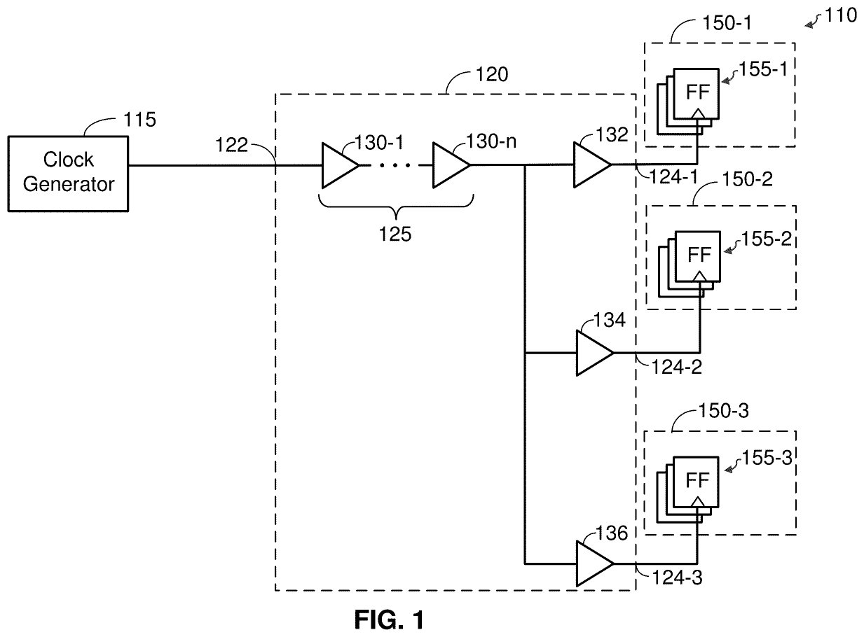

FIG. 1 shows an example of a system 110 including a clock generator 115, a clock distribution network 120, and multiple circuits 150-1 to 150-3 according to certain aspects. The clock generator 115 is configured to generate a clock signal for timing operations of the circuits 150-1 to 150-3. The clock generator 115 may be implemented with a phase-locked loop (PLL) or another type of clock generator 115. The clock distribution network 120 (also referred to as a clock tree) is configured to distribute the clock signal from the clock generator 115 to the circuits 150-1 to 150-3. As used herein, a “clock signal” may be a periodic signal that oscillates between high and low. A clock signal may be used, for example, to time operations of synchronous digital circuits or other types of circuits. A clock signal has a duty cycle, which may be expressed as a percentage or a fraction of a clock period (i.e., clock cycle) in which the clock signal is high (i.e., one).

In the example shown in FIG. 1, each of the circuits 150-1 to 150-3 may include respective flip-flops 155-1 to 155-3, which are clocked by the clock signal. It is to be appreciated that the circuits 150-1 to 150-3 are not limited to flip-flops and may include other devices in addition to or instead of the flip-flops 155-1 to 155-3.

In this example, the clock generator 115 is coupled to an input 122 of the clock distribution network 120, and each of the circuits 150-1 to 150-3 is coupled to a respective output 124-1 to 124-3 of the clock distribution network 120. The clock distribution network 120 receives the clock signal from the clock generator 115 via the input 122 (also referred to as a root node) and distributes the clock signal to the circuits 150-1 to 150-3 via the outputs 124-1 to 124-3 (also referred to as leaf nodes).

In the example shown in FIG. 1, the clock distribution network 120 includes a signal path 125, and delay buffers 132, 134, and 136 (also referred to as clock buffers). The signal path 125 includes delay buffers 130-1 to 130-n coupled in series. It is to be appreciated that the clock distribution network 120 may include additional delay buffers and/or other components not shown in FIG. 1. For example, the clock distribution network 120 may also include one or more clock gating circuits (also referred to as clock gating cells) to gate the clock signal when the circuits 150-1 to 150-3 are idle to reduce dynamic power consumption when the circuits 150-1 to 150-3 are idle. As used herein, a “signal path” is a path through which a signal (e.g., a clock signal) propagates, and may include one or more delay buffers and/or one or more other components.

A challenge with the clock distribution network 120 is duty cycle degradation in the clock distribution network 120. The duty cycle degradation results in duty cycle distortion in the clock signal, which can lead to timing issues (e.g., timing violations) in one or more of the circuits 150-1 to 150-3. For example, due to higher duty cycle degradation in advanced process nodes and higher lifetime requirements for automotive/compute applications, meeting clock duty cycle distortion requirements is becoming more challenging. Duty cycle degradation in the clock distribution network 120 may be caused, for example, by asymmetric aging in the clock distribution network 120 (e.g., asymmetric aging of transistors in the delay buffers 130-130-n, 132, 134, and 136), process variation, and/or one or more other causes.

To address duty cycle distortion, the system 110 may include one or more correction circuits where each correction circuit is configured to measure duty cycle distortion at a respective node in the clock distribution network 120 and correct for the duty cycle distortion based on the measurement. Precise duty cycle distortion measurements are important for duty cycle correction and meeting clock duty cycle distortion requirements.

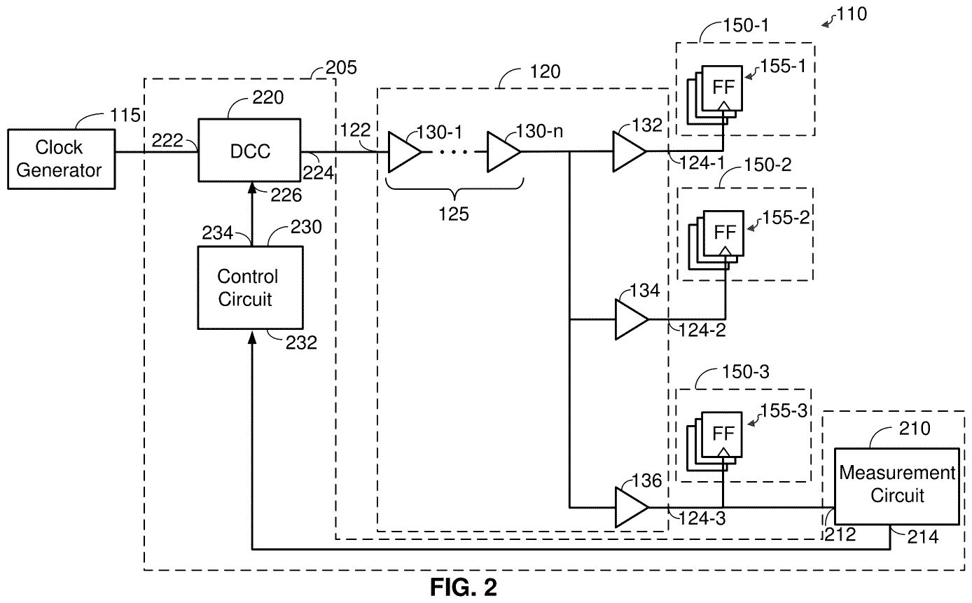

FIG. 2 shows an example of a correction circuit 205 configured to correct for duty cycle distortion in the clock distribution network 120 according to certain aspects. The correction circuit 205 includes a measurement circuit 210, a duty cycle corrector (DCC) 220, and a control circuit 230. The DCC 220 may also be referred to as a duty cycle adjuster, a duty cycle distortion (DCD) correction circuit or cell, or another term.

The measurement circuit 210 has an input 212 and an output 214. In the example in FIG. 2, the input 212 of the measurement circuit 210 is coupled to a node (e.g., output 124-3) of the clock distribution network 120. It is to be appreciated that the input 212 of the measurement circuit 210 is not limited to the exemplary node shown in FIG. 2 and that the input 212 of the measurement circuit 210 may be coupled to another node in other examples. The measurement circuit 210 is configured to receive the clock signal at the input 212, measure one or more timing parameters of the clock signal, and output a measurement signal indicating the measured one or more timing parameters. The one or more timing parameters provide information on the duty cycle of the clock signal at the node (e.g., output 124-3). As discussed further below, this information allows the control circuit 230 to determine the duty cycle distortion at the node and correct for the duty cycle distortion using the DCC 220.

The DCC 220 has a signal input 222, a control input 226, and an output 224. In the example shown in FIG. 2, the signal input 222 is coupled to the clock generator 115 and the output 224 is coupled to the input 122 of the clock distribution network 120. However, it is to be appreciated that the DCC 220 may be placed at other locations in the system 110 in other examples. For example, the DCC 220 may be placed at a location closer to the node coupled to the measurement circuit 210 in other examples. The DCC 220 is configured to receive the clock signal at the signal input 222, adjust the duty cycle of the clock signal (e.g., to correct for duty cycle distortion), and output the clock signal after the duty cycle adjustment at the output 224. The DCC 220 is configured to adjust the duty cycle of the clock signal based on a control signal received at the control input 226 from the control circuit 230, as discussed further below.

The control circuit 230 has an input 232 and an output 234. The input 232 is coupled to the output 214 of the measurement circuit 210 and the output 234 is coupled to the control input 226 of the DCC 220. The control circuit 230 is configured to receive the measurement signal from the measurement circuit 210, and set the duty cycle adjustment of the DCC 220 based on the measurement signal.

In certain aspects, the control circuit 230 corrects for duty cycle distortion by determining the duty cycle distortion of the clock signal at the node based on the measurement signal from the measurement circuit 210 and setting the duty cycle adjustment of the DCC 220 to correct for the duty cycle distortion. For example, the control circuit 230 may determine the duty cycle distortion of the clock signal at the node by determining the duty cycle of the clock signal at the node based on the measurement signal and determining the deviation of the duty cycle of the clock signal from a target duty cycle (e.g., 50% duty cycle). In this example, the deviation of the duty cycle of the clock signal from the target duty cycle indicates the duty cycle distortion.

The control circuit 230 may then set the DCC 220 to a duty cycle adjustment that reduces the deviation from the target duty cycle and, thus, reduce the duty cycle distortion. For example, if the duty cycle of the clock signal at the node is higher than the target duty cycle (e.g., 50%), then the control circuit 230 may set the DCC 220 to a duty cycle adjustment that decreases the duty cycle of the clock signal at the node. In this case, the decrease in the duty cycle reduces the deviation of the duty cycle from the target duty cycle, and, thus, reduces the duty cycle distortion. In another example, if the duty cycle of the clock signal at the node is lower than the target duty cycle (e.g., 50%), then the control circuit 230 may set the DCC 220 to a duty cycle adjustment that increases the duty cycle of the clock signal at the node. In this case, the increase in the duty cycle reduces the deviation of the duty cycle from the target duty cycle, and, thus, reduces the duty cycle distortion.

Thus, in this example, the correction circuit 205 measures the duty cycle distortion of the clock signal at the node and adjusts the duty cycle of the clock signal based on the measurement to correct for the duty cycle distortion. The correction circuit 205 may perform duty cycle distortion correction periodically, each time the system 110 is booted, before and/or after a high-temperature operating life (HTOL) stress test, etc.

It is to be appreciated that the measurement circuit 210 may be coupled to other nodes in the clock distribution network 120 besides the exemplary node shown in FIG. 2 to measure duty cycle distortion at other nodes in the clock distribution network 120. In some implementations, the correction circuit 205 may include two or more instances (i.e., copies) of the measurement circuit 210 coupled to different nodes in the clock distribution network 120 to measure duty cycle distortion at the different nodes. The correction circuit 205 may also include two or more instances of the DCC 220 to provide duty cycle distortion correction at two or more different locations in the clock distribution network 120.

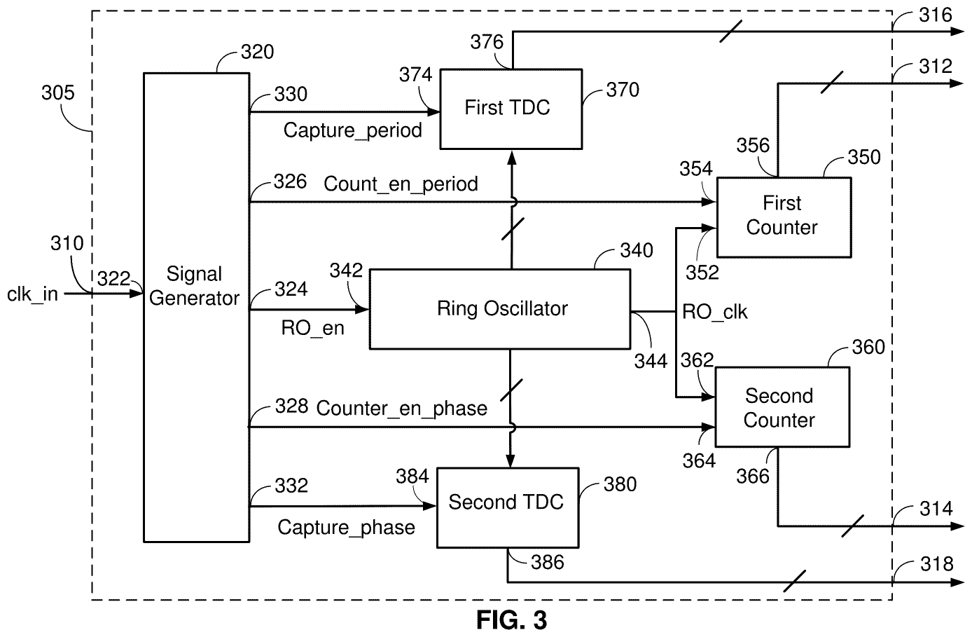

FIG. 3 shows an exemplary implementation of a measurement circuit 305 according to certain aspects of the present disclosure. The measurement circuit 305 includes a signal generator 320, a ring oscillator 340, a first counter 350, a second counter 360, a first time-to-digital converter (TDC) 370, and a second TDC 380. As discussed further below, the first TDC 370 and the second TDC 380 allow the measurement circuit 305 to make timing measurements with a resolution that is a fraction of a period of the ring oscillator 340.

The measurement circuit 305 may be used to implement the measurement circuit 210 in FIG. 2 to measure the duty cycle of the clock signal in the clock distribution network 120 for duty cycle distortion correction. However, it is to be appreciated that the measurement circuit 305 is not limited to this example. The measurement circuit 305 may also be used to measure voltage droop according to certain aspects, as discussed further below.

In the example shown in FIG. 3, the measurement circuit 305 has an input 310 configured to receive the clock signal clk_in. The input 310 may be coupled to a node (e.g., output 124-3) on the clock distribution network 120 for the example where the measurement circuit 305 implements the measurement circuit 210. In this example, the input 310 of the measurement circuit 305 corresponds to the input 212 in FIG. 2.

In the example shown in FIG. 3, the ring oscillator 340 has an enable input 342 and an output 344. The ring oscillator 340 is configured to receive an enable signal RO_en at the enable input 342 and enable oscillation in the ring oscillator 340 based on the enable signal RO_en. For example, the ring oscillator 340 may be configured to enable (i.e., activate) oscillation when the enable signal RO_en is high (i.e., logic one) and disable the oscillation when the enable signal RO_en is low (i.e., logic zero). However, it is to be appreciated that the ring oscillator 340 is not limited to this example. When enabled (i.e., active), the ring oscillator 340 is configured to output an oscillator signal RO_clk at the output 344, in which the oscillator signal RO_clk oscillates at the frequency of the ring oscillator 340.

The first counter 350 has an enable input 354, a count input 352 coupled to the output 344 of the ring oscillator 340, and an output 356. The first counter 350 is configured to receive a first count enable signal Count_en_period at the enable input 354 and enable counting in the first counter 350 based on the first count enable signal Count_en_period. For example, the first counter 350 may be configured to enable (i.e., activate) counting when the first count enable signal Count_en_period is high (i.e., logic one) and disable the counting when the first count enable signal Count_en_period is low (i.e., logic zero). However, it is to be appreciated that the first counter 350 is not limited to this example. When enabled (i.e., active), the first counter 350 counts a number of periods (i.e., cycles) of the oscillator signal RO_clk from the ring oscillator 340 and outputs a first count value at the output 356 indicating the count. When disabled, the first counter 350 may hold the current count until the first counter 350 is reset for the next count. As discussed further below, the first counter 350 may be used to measure the number of periods of the oscillator signal RO_clk in a period of the clock signal clk_in.

The second counter 360 has an enable input 364, a count input 362 coupled to the output 344 of the ring oscillator 340, and an output 366. The second counter 360 is configured to receive a second count enable signal Count_en_phase at the enable input 364 and enable counting in the second counter 360 based on the second count enable signal Count_en_phase. For example, the second counter 360 may be configured to enable (i.e., activate) counting when the second count enable signal Count_en_phase is high (i.e., logic one) and disable the counting when the second count enable signal Count_en_phase is low (i.e., logic zero). However, it is to be appreciated that the second counter 360 is not limited to this example. When enabled (i.e., active), the second counter 360 counts a number of periods (i.e., cycles) of the oscillator signal RO_clk from the ring oscillator 340 and outputs a second count value at the output 366 indicating the count. When disabled, the second counter 360 may hold the current count until the second counter 360 is reset for the next count. As discussed further below, the second counter 360 may be used to measure the number of periods of the oscillator signal RO_clk in a phase of the clock signal clk_in. The phase may be a high phase or a low phase, as discussed further below.

The signal generator 320 has an input 322, a first output 324, a second output 326, and a third output 328. The first output 324 is coupled to the enable input 342 of the ring oscillator 340, the second output 326 is coupled to the enable input 354 of the first counter 350, and the third output 328 is coupled to the enable input 364 of the second counter 360. The input 322 of the signal generator 320 is coupled to the input 310 of the measurement circuit 305 to receive the clock signal clk_in. In certain aspects, the frequency of the ring oscillator 340 is higher than the frequency of the clock signal clk_in such that one period of the oscillator signal RO_clk is shorter than one period of the clock signal clk_in.

The signal generator 320 is configured to generate the enable signal RO_en for the ring oscillator 340, the first count enable signal Count_en_period for the first counter 350, and the second count enable signal Count_en_phase for the second counter 360 based on the clock signal clk_in. The signal generator 320 outputs the enable signal RO_en at the first output 324, outputs the first count enable signal Count_en_period at the second output 326, and outputs the second count enable signal Count_en_phase at the third output 328.

In certain aspects, the signal generator 320 generates the above enable signals to measure the duty cycle of the clock signal clk_in. In this example, the signal generator 320 enables the ring oscillator 340 using the enable signal RO_en. For example, the signal generator 320 may enable the ring oscillator 340 for a duration approximately equal to one period of the clock signal clk_in or longer than one period of the clock signal clk_in.

While the ring oscillator 340 is enabled, the signal generator 320 enables the first counter 350 for a duration approximately equal to a period of the clock signal clk_in using the first count enable signal Count_en_period to count the number of periods of the oscillator signal RO_clk in the period of the clock signal clk_in. For the example where the first counter 350 is enabled (i.e., active) when the first count enable signal Count_en_period is high (i.e., logic one), the signal generator 320 enables the first counter 350 for the period of the clock signal clk_in by asserting the first count enable signal Count_en_period high for the duration of the period of the clock signal clk_in. This causes the first counter 350 to count the number of periods (i.e., cycles) of the oscillator signal RO_clk in the period of the clock signal clk_in.

After the period of the clock signal clk_in, the first counter 350 outputs the first count value at the output 356 indicating the number of periods of the oscillator signal RO_clk in the period of the clock signal clk_in. In this example, the first count value provides a measurement of the period of the clock signal clk_in with a resolution of one period of the oscillator signal RO_clk. The measurement circuit 305 may output the first count value (e.g., to the control circuit 230 in FIG. 2) via output 312. In certain aspects, the measurement circuit 305 may include registers (not shown) for temporarily storing the first count value before outputting the first count value via the output 312.

While the ring oscillator 340 is enabled, the signal generator 320 enables the second counter 360 for a duration approximately equal to a phase of the clock signal clk_in using the second count enable signal Count_en_phase to count the number of periods of the oscillator signal RO_clk in the phase of the clock signal clk_in. The phase may be a high phase or a low phase of the clock signal clk_in. As used herein, a high phase is the portion of a period of the clock signal clk_in during which the clock signal clk_in is high, and a low phase is the portion of a period of the clock signal clk_in during which the clock signal clk_in is low. For the example where the second counter 360 is enabled (i.e., active) when the second count enable signal Count_en_phase is high (i.e., logic one), the signal generator 320 enables the second counter 360 for the phase of the clock signal clk_in by asserting the second count enable signal Count_en_phase high for the duration of the phase the clock signal clk_in. This causes the second counter 360 to count the number of periods (i.e., cycles) of the oscillator signal RO_clk in the phase (e.g., high phase or low phase) of the clock signal clk_in.

After the phase of the clock signal clk_in, the second counter 360 outputs the second count value at the output 366 indicating the number of periods of the oscillator signal RO_clk in the phase of the clock signal clk_in. In this example, the second count value provides a measurement of the phase (e.g., high phase or low phase) of the clock signal clk_in with a resolution of one period of the oscillator signal RO_clk. The measurement circuit 305 may output the second count value (e.g., to the control circuit 230 in FIG. 2) via output 314. In certain aspects, the measurement circuit 305 may include registers (not shown) for temporarily storing the second count value before outputting the second count value via the output 314.

In this example, the control circuit 230 (shown in FIG. 2) may receive the first count value and the second value from the measurement circuit 305. The first count value provides the control circuit 230 with a measurement of the period of the clock signal clk_in and the second value provides the control circuit 230 with a measurement of the phase (e.g., high phase or low phase) of the clock signal clk_in. In this example, the control circuit 230 may determine the duty cycle of the clock signal clk_in based on the first count value and the second count value. For the example where the second count value provides a measurement of the high phase of the clock signal clk_in, the control circuit 230 may determine the duty cycle, for example, by dividing the second count value by the first count value. The control circuit 230 may also determine the duty cycle for the example where the second count value provides a measurement of the low phase of the clock signal clk_in since the high phase of the clock signal clk_in is equal to the period of the clock signal clk_in minus the low phase of the clock signal clk_in. Thus, the control circuit 230 may determine the duty cycle of the clock signal clk_in using either a high phase measurement or a low phase measurement of the clock signal clk_in. After determining the duty cycle of the clock signal clk_in, the control circuit 230 may determine the duty cycle distortion of the clock signal clk_in and set the duty cycle adjustment of the DCC 220 to correct the duty cycle distortion as discussed above with reference to FIG. 2.

In the above example, the first count value and the second count value have a resolution of one period of the ring oscillator 340. As discussed further below, the first TDC 370 and the second TDC 380 may be used to provide period and phase measurements with a resolution that is finer than one period of the ring oscillator 340. The higher resolution provides more precise timing measurements for more precise duty cycle distortion correction.

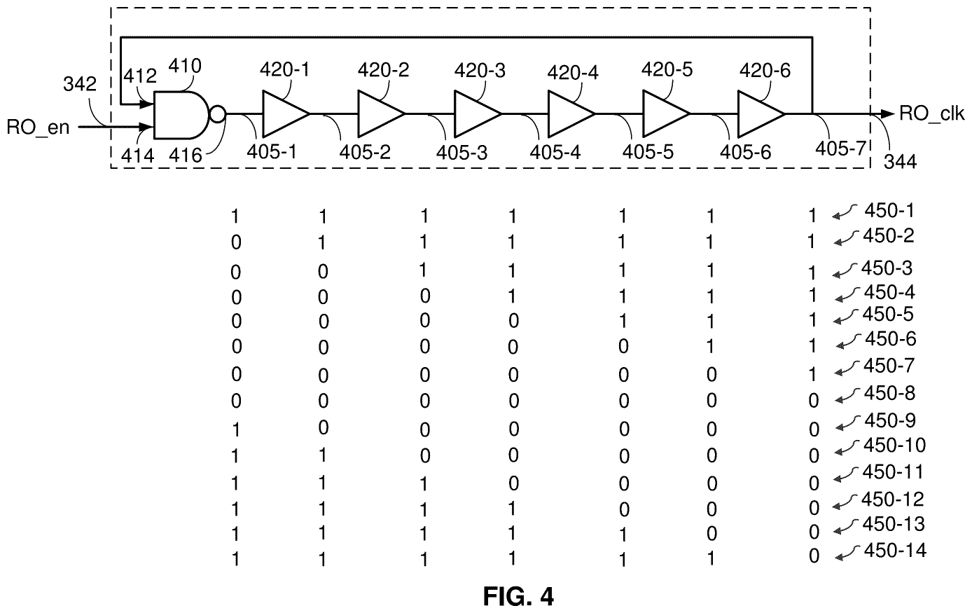

The first TDC 370 has a capture input 374 coupled to the signal generator 320 and an output 376. The first TDC 370 is coupled to multiple internal nodes (not shown in FIG. 3) of the ring oscillator 340. Examples of the internal nodes are discussed below with reference to FIG. 4 according to certain aspects. The first TDC 370 is configured to receive a first capture signal Capture_period at the capture input 374 and latch the logic states at the internal nodes of the ring oscillator 340 on an edge (e.g., rising edge or falling edge) of the first capture signal Capture_period. As discussed further below, the latched logic states provide a measurement of the elapsed time in the current period of the oscillator signal RO_clk.

The first TDC 370 may then output a first digital time signal including the latched logic states at the output 376. The first digital time signal may be output to the control circuit 230 via the output 316. As discussed further below, the first digital time signal may be used in combination with the first count value from the first counter 350 to provide a measurement of the period of the clock signal clk_in with a resolution that is a fraction of a period of the oscillator signal RO_clk. Thus, in this example, the first digital time signal enhances the resolution of the period measurement.

The second TDC 380 has a capture input 384 coupled to the signal generator 320 and an output 386. The second TDC 380 is coupled to the multiple internal nodes (not shown in FIG. 3) of the ring oscillator 340. The second TDC 380 is configured to receive a second capture signal Capture_phase at the capture input 384 and latch the logic states at the internal nodes of the ring oscillator 340 on an edge (e.g., rising edge or falling edge) of the second capture signal Capture_phase. As discussed further below, the latched logic states provide a measurement of the elapsed time in the current period of the oscillator signal RO_clk.

The second TDC 380 may then output a second digital time signal including the latched logic states at the output 386. The second digital time signal may be output to the control circuit 230 via the output 318. As discussed further below, the second digital time signal may be used in combination with the second count value from the second counter 360 to provide a measurement of the phase (e.g., high phase or low phase) of the clock signal clk_in with a resolution that is a fraction of a period of the oscillator signal RO_clk. Thus, in this example, the second digital time signal enhances the resolution of the phase measurement.

The signal generator 320 is configured to generate the first capture signal Capture_period and the second capture signal Capture_phase based on the clock signal clk_in. The signal generator 320 outputs the first capture signal Capture_period to the capture input 374 of the first TDC 370 via a fourth output 330 and outputs the second capture signal Capture_phase to the capture input 384 of the second TDC 380 via a fifth output 332.

In certain aspects, the signal generator 320 may align an edge of the first capture signal Capture_period with the end of the period of the clock signal clk_in to cause the first TDC to latch the logic states at the internal nodes of the ring oscillator 340 at the end of the period of the clock signal clk_in. As discussed above, the first TDC 370 is configured to latch the logic states at the internal nodes of the ring oscillator 340 on the edge (e.g., rising edge or falling edge) of the first capture signal Capture_period.

The signal generator 320 may align an edge of the second capture signal Capture_phase with the end of the phase of the clock signal clk_in to cause the second TDC to latch the logic states at the internal nodes of the ring oscillator 340 at the end of the phase of the clock signal clk_in. However, it is to be appreciated that the present disclosure is not limited to this example. As discussed above, the second TDC 380 is configured to latch the logic states at the internal nodes of the ring oscillator 340 on the edge (e.g., rising edge or falling edge) of the second capture signal Capture_phase.

FIG. 4 shows an exemplary implementation of the ring oscillator 340 according to certain aspects. In this example, the ring oscillator 340 includes delay buffers 420-1 to 420-6 coupled in a chain (i.e., series) in which the output of each of the delay buffers 420-1 to 420-5 is coupled to the input of the next delay buffer 420-2 to 420-6 in the chain. Each of the delay buffers 420-1 to 420-6 may include two inverters coupled in series. However, it is to be appreciated that the delay buffers 420-1 to 420-6 are not limited to this example. Although six delay buffers 420-1 to 420-6 are shown in the example in FIG. 4, it is to be appreciated that the ring oscillator 340 may include a different number of delay buffers in other examples.

In the example shown in FIG. 4, the ring oscillator 340 also includes a NAND gate 410 having a first input 412, a second input 414, and an output 416. The first input 412 is coupled to the output of the last delay buffer 420-6 in the chain and the output 416 of the NAND gate 410 is coupled to the input of the first delay buffer 420-1 in the chain. The second input 414 is coupled to the enable input 342 of the ring oscillator 340.

In the example shown in FIG. 4, the output 344 of the ring oscillator 340 is coupled to the output of the last delay buffer 420-6 in the chain. However, it is to be appreciated that the output 344 may be coupled to the output of another one of the delay buffers in other examples.

In this example, the ring oscillator 340 is enabled (i.e., active) when the enable signal RO_en is high (i.e., one) and disabled (i.e., inactive) when the enable signal RO_en is low (i.e., zero). When the enable signal RO_en is low, the NAND gate 410 outputs a one regardless of the logic state at the first input 412, which prevents the ring oscillator 340 from oscillating. When the enable signal RO_en is high, the NAND gate 410 inverts the logic state at the first input 412 and outputs the inverted logic state at the output 416. In this case, the NAND gate 410 acts as an inverter that is coupled with the delay buffers 420-1 to 420-6 in a loop, which causes the ring oscillator 340 to oscillate.

FIG. 4 shows an example of logic states at the internal nodes 405-1 to 405-7 of the ring oscillator 340 at different times during a period of the oscillator signal RO_clk. In this example, the node 405-1 is located at the output 416 of the NAND gate 410 and each of the nodes 405-2 to 405-7 is located at the output of a respective one of the delay buffers 420-1 to 420-6. In FIG. 4, the logic states are shown in rows 450-1 to 450-14 where each row shows the logic states at the nodes 405-1 to 405-7 at a respective time during the period of the oscillator signal RO_clk. For example, the first row 450-1 may show the logic states at the nodes 405-1 to 405-7 at the beginning of the period of the oscillator signal RO_clk and the last row 450-14 may show the logic states at the nodes 405-1 to 405-7 just before the start of the next period of the oscillator signal RO_clk. However, it is to be appreciated that the present disclosure is not limited to this example.

As shown in FIG. 4, the logic states at the nodes 405 to 405-7 can be used to measure the elapsed time within the current period of the oscillator signal RO_clk. As discussed further below, this allows the first TDC 370 to enhance the resolution of the period measurement to a fraction of a period of the oscillator signal RO_clk and allows the second TDC 380 to enhance the resolution of the phase measurement to a fraction of a period of the oscillator signal RO_clk.

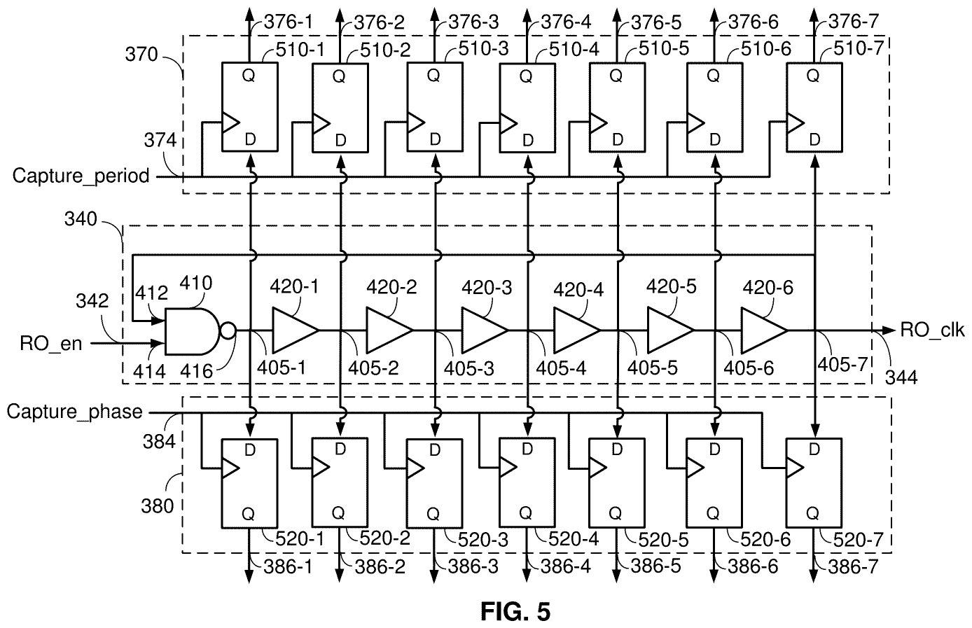

FIG. 5 shows an exemplary implementation of the first TDC 370 and the second TDC 380 according to certain aspects. In this example, the first TDC 370 includes flip-flops 510-1 to 510-7. Each of the flip-flops 510-1 to 510-7 has a respective signal input (labeled “D”), a respective output (labeled “Q”), and a respective clock input (represented by a triangle). In this example, the output 376 of the TDC 370 includes multiple outputs 376-1 to 376-7 where each of the outputs 376-1 to 376-7 is coupled to the output of a respective one of the flip-flops 510-1 to 510-7. The signal input of each of the flip-flops 510-1 to 510-7 is coupled to a respective one of the internal nodes 405-1 to 405-7 in the ring oscillator 340. The clock inputs of the flip-flops 510-1 to 510-7 are coupled to the capture input 374 of the first TDC 370.

In certain aspects, each of the flip-flops 510-1 to 510-7 is configured to latch the logic state at the respective one of the nodes 405-1 to 405-7 on an edge (e.g., rising edge or falling edge) of the first capture signal Capture_period, and output the latched logic state at the respective one of the outputs 376-1 to 376-7. As discussed above, in some implementations, the signal generator 320 may align the edge of the first capture signal Capture_period with the end of the period of the clock signal clk_in. In this example, the flip-flops 510-1 to 510-7 latch the logic states at the respective nodes 405-1 to 405-7 of the ring oscillator 340 at the end of the period of the clock signal clk_in and output the latched logic states at the respective outputs 376-1 to 376-7. The latched logic states provide the first digital time signal discussed above.

The latched logic states output by the first TDC 370 may be used in combination with the first count value from the first counter 350 to provide a measurement of the period of the clock signal clk_in with a resolution that is a fraction of a period of the oscillator signal RO_clk. In this example, the measurement of the period of the clock signal clk_in may have an integer portion and a fractional portion in which the integer portion is provided by the first count value from the first counter 350 and the fractional portion is provided by the latched logic states from the first TDC 370. In this example, the integer portion of the measurement represents a number of periods of the oscillator signal RO_clk and the fractional portion of the measurement represents a fraction of a period of the oscillator signal RO_clk.

In this example, the second TDC 380 includes flip-flops 520-1 to 520-7. Each of the flip-flops 520-1 to 520-7 has a respective signal input (labeled “D”), a respective output (labeled “Q”), and a respective clock input (represented by a triangle). In this example, the output 386 of the TDC 380 includes multiple outputs 386-1 to 386-7 where each of the outputs 386-1 to 386-7 is coupled to the output of a respective one of the flip-flops 520-1 to 520-7. The signal input of each of the flip-flops 520-1 to 520-7 is coupled to a respective one of the internal nodes 405-1 to 405-7 in the ring oscillator 340. The clock inputs of the flip-flops 520-1 to 520-7 are coupled to the capture input 384 of the second TDC 380.

In certain aspects, each of the flip-flops 520-1 to 520-7 is configured to latch the logic state at the respective one of the nodes 405-1 to 405-7 on an edge (e.g., rising edge or falling edge) of the second capture signal Capture_phase, and output the latched logic state at the respective one of the outputs 386-1 to 386-7. As discussed above, in some implementations, the signal generator 320 may align the edge of the second capture signal Capture_phase with the end of the phase (e.g., high phase or low phase) of the clock signal clk_in. In this example, the flip-flops 520-1 to 520-7 latch the logic states at the respective nodes 405-1 to 405-7 of the ring oscillator 340 at the end of the phase of the clock signal clk_in and output the latched logic states at the respective outputs 386-1 to 386-7. The latched logic states provide the second digital time signal discussed above.

The latched logic states output by the second TDC 380 may be used in combination with the second count value from the second counter 360 to provide a measurement of the phase (e.g., high phase or low phase) of the clock signal clk_in with a resolution that is a fraction of a period of the oscillator signal RO_clk. In this example, the measurement of the phase of the clock signal clk_in may have an integer portion and a fractional portion in which the integer portion is provided by the second count value from the second counter 360 and the fractional portion is provided by the latched logic states from the second TDC 380. In this example, the integer portion of the measurement represents a number of periods of the oscillator signal RO_clk and the fractional portion of the measurement represents a fraction of a period of the oscillator signal RO_clk.

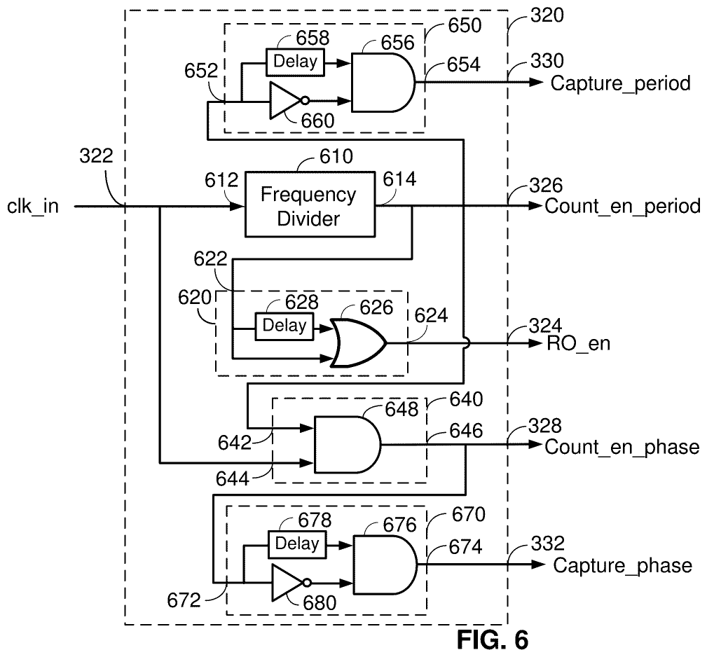

FIG. 6 shows an exemplary implementation of the signal generator 320 according to certain aspects. In this example, the signal generator 320 includes a frequency divider 610 having an input 612 coupled to the input 322 of the signal generator 320 and an output 614 coupled to the second output 326 of the signal generator 320. The frequency divider 610 may be a divider-by-two divider configured to divide the frequency of the clock signal clk_in by two to generate the first count enable signal Count_en_period.

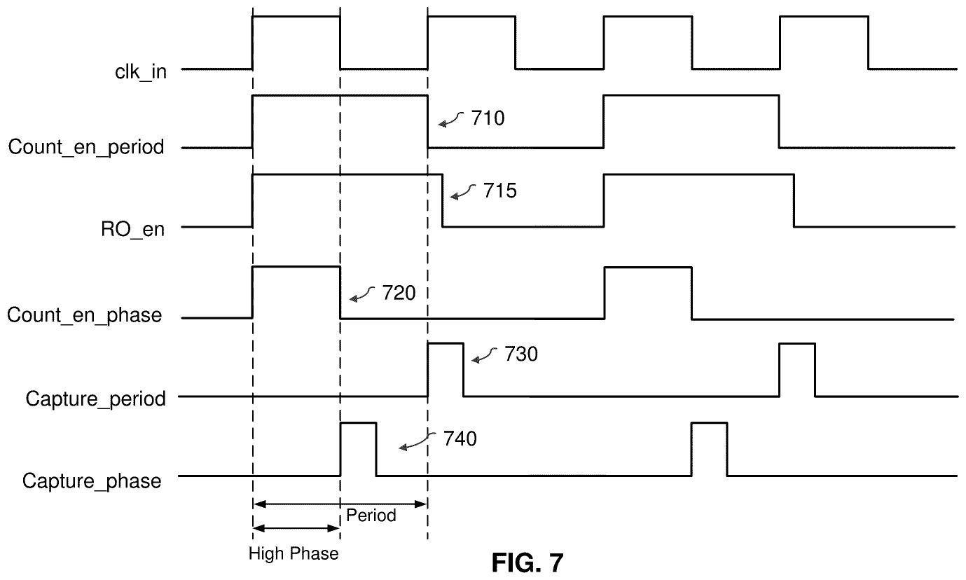

An example of the first count enable signal Count_en_period is shown in the timing diagram in FIG. 7. As shown in the example in FIG. 7, the first count enable signal Count_en_period is high (i.e., logic one) for a duration approximately equal to the period of the clock signal clk_in (i.e., the Count_en_period includes a pulse 710 having a length approximately equal to the period of the clock signal clk_in). For the example where the first counter 350 is enabled (i.e., active) when the first count enable signal Count_en_period is high, this causes the first counter 350 to count the number of periods of the oscillator signal RO_clk in the period of the clock signal clk_in. In the example in FIG. 7, the first count enable signal Capture_en_period is high for every other period of the clock signal clk_in. This allows the measurement circuit 305 to measure one period of the clock signal clk_in during every other period of the clock signal clk_in.

In the example in FIG. 6, the signal generator 320 also includes a pulse stretcher 620 having an input 622 coupled to the output 614 of the frequency divider 610 and an output 624 coupled to the first output 324 of the signal generator 320. The pulse stretcher 620 receives the first count enable signal Count_en_period from the frequency divider 610 and stretches the pulse 710 of the first count enable signal Count_en_period to generate the enable signal RO_en for the ring oscillator 340. In the exemplary timing diagram shown in FIG. 7, the pulse stretching causes the pulse 715 of the enable signal RO_en to extend slightly beyond the period of the clock signal clk_in. As a result, in this example, the ring oscillator 340 is enabled (i.e., active) for a time duration slightly longer than the period of the clock signal clk_in. This may be done, for example, to meet timing requirements (e.g., hold times) for the flip-flops 510-1 to 510-7 in the first TDC 370. In the example in FIG. 6, the pulse stretcher 620 includes an OR gate 626 and a delay element 628, in which the delay of the delay element 628 controls the amount of pulse stretching.

In the example in FIG. 6, the signal generator 320 also includes a clock gating circuit 640 having a first input 642 coupled to the output 614 of the frequency divider 610, a second input 644 coupled to the input 322 of the signal generator 320, and an output 646 coupled to the third output 328 of the signal generator 320. In this example, the clock gating circuit 640 may be configured to receive the first count enable signal Capture_period from the frequency divider 610 and selectively gate the first count enable signal Capture_period based on the logic state of the clock signal clk_in to generate the second count enable signal Count_en_phase. In this regard, FIG. 7 shows an example in which the clock gating circuit 640 passes the first count enable signal Count_en_period when the clock signal clk_in is high and gates the first count enable signal Count_en_period when the clock signal clk_in is low. This causes the second count enable signal Count_en_phase to be high during the high phase of the clock signal clk_in in this example (i.e., the second count enable signal Count_en_phase includes a pulse 720 approximately equal to the phase of the clock signal clk_in). For the example where the second counter 360 is enabled when the second count enable signal Count_en_phase is high, the second count enable signal Count_en_phase enables the second counter 360 during the high phase of the clock signal clk_in. As a result, the second counter 360 counts the number of periods of the oscillator signal RO_clk in the high phase of the clock signal clkin in this example. In the example in FIG. 6, the clock gating circuit 640 includes an AND gate 648, but is not limited to this example.

It is to be appreciated that the clock gating circuit 640 is not limited the above example. In another implementation, the clock gating circuit 640 may be configured to pass the first count enable signal Count_en_period when the clock signal clk_in is low and gate the first count enable signal Count_en_period when the clock signal clk_in is high. In this example, the second count enable signal Count_en_phase is high during the low phase of the clock signal clk_in and the second counter 360 counts the number of periods of the oscillator signal RO_clk in the low phase of the clock signal clk_in.

In the example in FIG. 6, the signal generator 320 also includes a first pulse generator 650 having an input 652 coupled to the output 614 of the frequency divider 610 and an output 654 coupled to the fourth output 330 of the signal generator 320. In this example, the first pulse generator 650 may be configured to generate a positive pulse 730 on a falling edge of the first count enable signal Count_en_period to generate the first capture signal Capture_period. As shown in the example in FIG. 7, this results in the first capture signal Capture_period having a rising edge (i.e., positive edge) approximately aligned with the end of the period of the clock signal clk_in. For the example where the flip-flops 510-1 to 510-7 in the first TDC 370 are positive-edge triggered, this causes the flip-flops 510-1 to 510-7 to latch the logic states at the nodes 405-1 to 405-7 at approximately the end of the period of the clock signal clk_in. In the example in FIG. 6, the first pulse generator 650 includes an inverter 660, a delay element 658, and an AND gate 656, but is not limited to this example. In this example, the delay of the delay element 658 controls the width of the pulse 730.

In the example in FIG. 6, the signal generator 320 also includes a second pulse generator 670 having an input 672 coupled to the output 646 of the clock gating circuit 640 and an output 674 coupled to the fifth output 332 of the signal generator 320. In this example, the second pulse generator 670 may be configured to generate a positive pulse 740 on a falling edge of the second count enable signal Count_en_phase to generate the second capture signal Capture_phase. As shown in the example in FIG. 7, this results in the second capture signal Capture_phase having a rising edge (i.e., positive edge) approximately aligned with the end of the high phase of the clock signal clk_in. For the example where the flip-flops 520-1 to 520-7 in the second TDC 380 are positive-edge triggered, this causes the flip-flops 520-1 to 520-7 to latch the logic states at the nodes 405-1 to 405-7 at approximately the end of the high phase of the clock signal clk_in. However, it is to be appreciated that the second pulse generator 670 is not limited to this example. In the example in FIG. 6, the second pulse generator 670 includes an inverter 680, a delay element 678, and an AND gate 676, but is not limited to this example. In this example, the delay of the delay element 678 controls the width of the pulse 740.

As discussed above, the measurement circuit 305 may be used to provide period and phase measurements for determining the duty cycle of the clock signal clk_in for duty cycle distortion correction. However, the measurement circuit 305 is not limited to this example. For example, the period measurements from the measurement circuit 305 may also be used to measure the voltage droops in a power distribution network (PDN). Current load fluctuations on the PDN can cause voltage droops in the PDN, which impact the performance of circuits coupled to the PDN. As a result, voltage droop is a major reliability concern in nanoscale SoC designs, which leads to an increase in path delays and the occurrence of intermittent soft faults during circuit operation. Therefore, an accurate voltage droop measurement circuit is desirable to relax timing margins and improve the performance of the circuits coupled to the PDN.

The period measurements from the measurement circuit 305 may be used to measure voltage droop because the frequency of the ring oscillator 340 is directly proportional to the supply voltage of the PDN for the case where the ring oscillator 340 receives power from the PDN. As a result, the periods of the oscillator signal RO_clk are a function of voltage droop in the PDN. The larger the voltage droop, the lower the frequency of the ring oscillator 340 and hence the longer the periods of the oscillator signal RO_clk. As a result, the voltage droop may cause the number of periods of the oscillator signal RO_clk in the period of the clock signal clk_in to decrease, and hence cause the first count value from the first counter 350 to decrease. Because voltage droop affects both period and phase equally, the duty cycle measurements will not be affected.

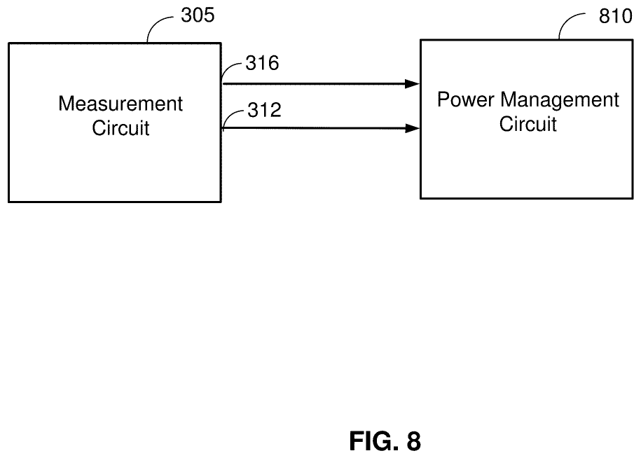

Thus, the period measurements from the measurement circuit 305 may be observed over multiple periods (i.e., cycles) to monitor voltage fluctuations (e.g., voltage droops) in the PDN. In this regard, FIG. 8 shows an example in which the measurement circuit 305 is coupled to a power management circuit 810 according to certain aspects. In this example, the power management circuit 810 receives period measurements from the measurement circuit 305 and uses the period measurements to monitor voltage fluctuations in the PDN. For example, the power management circuit 810 may use the period measurements to detect a large voltage droop in the PDN (e.g., by detecting a decrease in the first count value due to lower oscillation frequency caused by the large voltage droop). In response to detection of the large voltage droop, the power management circuit 810 may take steps to mitigate the voltage droop including, for example, reducing the frequency of the clock signal clk_in to prevent the voltage droop from causing timing violations, increasing the supply voltage to meet performance requirements, and/or other steps.

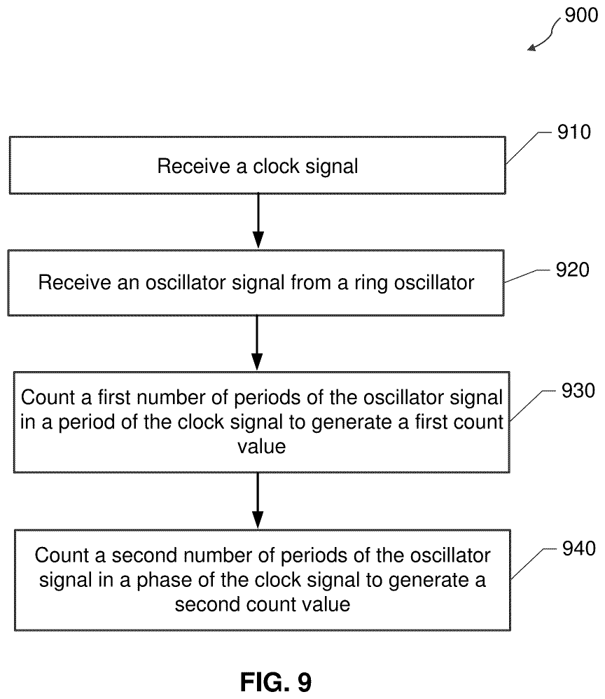

FIG. 9 illustrates a measurement method 900 according to certain aspects of the present disclosure.

At block 910, a clock signal is received. For example, the clock signal may correspond to the clock signal clk_in.

At block 920, an oscillator signal from a ring oscillator is received. For example, the ring oscillator may correspond to the ring oscillator 340.

At block 930, a first number of periods of the oscillator signal in a period of the clock signal are counted to generate a first count value. For example, the first number of periods of the clock signal in the period of the clock signal may be counted by the first counter 350.

At block 940, a second number of periods of the oscillator signal in a phase of the clock signal are counted to generate a second count value. For example, the second number of periods of the clock signal in the phase of the clock signal may be counted by the second counter 360. The phase of the clock signal may be a high phase of the clock signal or a low phase of the clock signal.

In certain aspects, the method 900 may further include determining a duty cycle of the clock signal based on the first count value and the second count value. For example, the control circuit 230 may determine the duty cycle of the clock signal based on the first count value and the second count value.

In certain aspects, the method 900 may further include latching first logic states at internal nodes of the ring oscillator at an end of the period of the clock signal, and latching second logic states at the internal nodes of the ring oscillator at the end of the phase of the clock signal. For example, the first TDC 370 may latch the first logic states and the second TDC 380 may latch the second logic states.

In certain aspects, the method 900 may further include generating a period measurement based on the first count value and the latched first logic states, and generating a phase measurement based on the second count value and the latched second logic states. For example, the first count value may provide an integer portion of the period measurement and the latched first logic states may provide a fractional portion of the period measurement. Also, the second count value may provide an integer portion of the phase measurement and the second latched logic states may provide a fractional portion of the phase measurement.

In certain aspects, the method 900 may further include determining a duty cycle of the clock signal based on the period measurement and the phase measurement. For example, the control circuit 230 may determine the duty cycle.

Implementation examples are described in the following numbered clauses:

1. A measurement circuit, comprising:
a ring oscillator;
a first counter coupled to an output of the ring oscillator;
a second counter coupled to the output of the ring oscillator; and
a signal generator configured to:
receive a clock signal;
generate a first count enable signal based the clock signal and output the first count enable signal to the first counter; and
generate a second count enable signal based on the clock signal and output the second count enable signal to the second counter.

2. The measurement circuit of clause 1, wherein the first count enable signal enables the first counter for a duration approximately equal to a period of the clock signal, and the second count enable signal enables the second counter for a duration approximately equal to a phase of the clock signal.

3. The measurement circuit of clause 2, wherein the phase of the clock signal is a high phase of the clock signal.

4. The measurement circuit of clause 2, wherein the phase of the clock signal is a low phase of the clock signal.

5. The measurement circuit of any one of clauses 2 to 4, wherein the first counter is configured to enable counting in the first counter when the first count enable signal is high, and the first count enable signal includes a first pulse having a first length approximately equal to the period of the clock signal.

6. The measurement circuit of clause 5, wherein the second counter is configured to enable counting in the second counter when the second count enable signal is high, and the second count enable signal includes a second pulse having a second length approximately equal to the phase of the clock signal.

7. The measurement circuit of any one of clauses 2 to 6, wherein the signal generator is configured to enable the ring oscillator during the period of the clock signal.

8. The measurement circuit of any one of clauses 2 to 7, further comprising a first time-to-digital converter (TDC) coupled to internal nodes of the ring oscillator.

9. The measurement circuit of clause 8, wherein the signal generator is configured to generate a capture signal and output the capture signal to the first TDC, and the first TDC is configured to latch logic states at the internal nodes of the ring oscillator on an edge of the capture signal and output the latched logic states.

10. The measurement circuit of clause 9, wherein the signal generator is configured to align the edge of the capture signal with an end of the period of the clock signal.

11. The measurement circuit of clause 10, wherein the edge is a rising edge.

12. The measurement circuit of any one of clauses 8 to 11, further comprising a second TDC coupled to the internal nodes of the ring oscillator.

13. The measurement circuit of clause 12, wherein the signal generator is configured to generate a capture signal and output the capture signal to the second TDC, and the second TDC is configured to latch logic states at the internal nodes of the ring oscillator on an edge of the capture signal and output the latched logic states.

14. The measurement circuit of clause 13, wherein the signal generator is configured to align the edge of the capture signal with an end of the phase of the clock signal.

15. The measurement circuit of clause 14, wherein the edge is a rising edge.

16. The measurement circuit of any one of clauses 8 to 15, wherein the ring oscillator comprises delay buffers coupled in a loop, and each of the internal nodes is located at an output of a respective one of the delay buffers.

17. The measurement circuit of any one of clauses 1 to 16, wherein the signal generator is coupled to a node on a clock distribution network, and the signal generator is configured to receive the clock signal from the node of the clock distribution network.

18. The measurement circuit of clause 17, wherein the clock distribution network distributes the clock signal from a clock generator to one or more circuits coupled to the clock distribution circuit.

19. A measurement method, comprising:
receiving a clock signal;
receiving an oscillator signal from a ring oscillator;
counting a first number of periods of the oscillator signal in a period of the clock signal to generate a first count value; and
counting a second number of periods of the oscillator signal in a phase of the clock signal to generate a second count value.

20. The method of clause 19, wherein the phase of the clock signal is a high phase of the clock signal.

21. The method of clause 19, wherein the phase of the clock signal is a low phase of the clock signal.

22. The method of any one of clauses 19 to 21, further comprising determining a duty cycle of the clock signal based on the first count value and the second count value.

23. The method of any one of clauses 19 to 22, further comprising:
latching first logic states at internal nodes of the ring oscillator at an end of the period of the clock signal; and
latching second logic states at the internal nodes of the ring oscillator at an end of the phase of the clock signal.

24. The method of clause 23, further comprising:
generating a period measurement based on the first count value and the latched first logic states; and
generating a phase measurement based on the second count value and the latched second logic states.

25. The method of clause 24, further comprising determining a duty cycle of the clock signal based on the period measurement and the phase measurement.

26. The method of any one of clauses 19 to 25, further comprising:
generating multiple phase measurements of the clock signal; and
detecting a voltage droop based on the multiple phase measurements.

27. The method of clause 26, wherein generating the multiple phase measurement comprises, for each of the multiple phase measurements, counting a number of periods of the oscillator signal in a respective one of multiple periods of the clock signal.

It is to be appreciated that the present disclosure is not limited to the exemplary terminology used above to describe aspects of the present disclosure. For example, a clock generator may also be referred to as a clock source, a clock synthesizer, or another term. In another example, a delay buffer may also be referred to as a delay element, a delay unit, or another term. A signal path used for the clock signal may also be referred to as a clock path.

The control circuit 230 may be implemented with a general-purpose processor, a digital signal processor (DSP), an application specific integrated circuit (ASIC), a field programmable gate array (FPGA) or other programmable logic device, discrete hardware components (e.g., logic gates), a state machine, or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. The term “approximately” means within 10 percent of the stated value (i.e., within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A measurement circuit, comprising:
a ring oscillator;
a first counter coupled to an output of the ring oscillator;
a second counter coupled to the output of the ring oscillator; and
a signal generator configured to:
receive a clock signal;
generate a first count enable signal based the clock signal and output the first count enable signal to the first counter; and
generate a second count enable signal based on the clock signal and output the second count enable signal to the second counter.

2. The measurement circuit of claim 1, wherein the first count enable signal enables the first counter for a duration approximately equal to a period of the clock signal, and the second count enable signal enables the second counter for a duration approximately equal to a phase of the clock signal.

3. The measurement circuit of claim 2, wherein the phase of the clock signal is a high phase of the clock signal.

4. The measurement circuit of claim 2, wherein the phase of the clock signal is a low phase of the clock signal.

5. The measurement circuit of claim 2, wherein the first counter is configured to enable counting in the first counter when the first count enable signal is high, and the first count enable signal includes a first pulse having a first length approximately equal to the period of the clock signal.

6. The measurement circuit of claim 5, wherein the second counter is configured to enable counting in the second counter when the second count enable signal is high, and the second count enable signal includes a second pulse having a second length approximately equal to the phase of the clock signal.

7. The measurement circuit of claim 2, wherein the signal generator is configured to enable the ring oscillator during the period of the clock signal.

8. The measurement circuit of claim 2, further comprising a first time-to-digital converter (TDC) coupled to internal nodes of the ring oscillator.

9. The measurement circuit of claim 8, wherein the signal generator is configured to generate a capture signal and output the capture signal to the first TDC, and the first TDC is configured to latch logic states at the internal nodes of the ring oscillator on an edge of the capture signal and output the latched logic states.

10. The measurement circuit of claim 9, wherein the signal generator is configured to align the edge of the capture signal with an end of the period of the clock signal.

11. The measurement circuit of claim 10, wherein the edge is a rising edge.

12. The measurement circuit of claim 8, further comprising a second TDC coupled to the internal nodes of the ring oscillator.

13. The measurement circuit of claim 12, wherein the signal generator is configured to generate a capture signal and output the capture signal to the second TDC, and the second TDC is configured to latch logic states at the internal nodes of the ring oscillator on an edge of the capture signal and output the latched logic states.

14. The measurement circuit of claim 13, wherein the signal generator is configured to align the edge of the capture signal with an end of the phase of the clock signal.

15. The measurement circuit of claim 14, wherein the edge is a rising edge.

16. The measurement circuit of claim 8, wherein the ring oscillator comprises delay buffers coupled in a loop, and each of the internal nodes is located at an output of a respective one of the delay buffers.

17. A measurement method, comprising:
receiving a clock signal;
receiving an oscillator signal from a ring oscillator;
counting a first number of periods of the oscillator signal in a period of the clock signal to generate a first count value; and
counting a second number of periods of the oscillator signal in a phase of the clock signal to generate a second count value.

18. The method of claim 17, wherein the phase of the clock signal is a high phase of the clock signal.

19. The method of claim 17, wherein the phase of the clock signal is a low phase of the clock signal.

20. The method of claim 17, further comprising determining a duty cycle of the clock signal based on the first count value and the second count value.
